(19) United States
(12) Patent Application Publication
(10) Pub. No.: US 2026/0141148 A1
(43) Pub. Date: May 21, 2026

(54) MACHINE-LEARNING-BASED INTEGRATED CIRCUIT TESTING

(71) Applicant: QUALCOMM Incorporated, San Diego, CA (US)

(72) Inventors: Sanket Vinod THAKUR, San Diego, CA (US); Enrique DE LA ROSA, San Diego, CA (US); Lindsey Makana KOSTAS, San Diego, CA (US)

(21) Appl. No.: 18/949,235

(22) Filed: Nov. 15, 2024

(51) Int. Cl. G06F 30/333; G06N 20/20

(52) U.S. Cl. CPC G06F 30/333; G06N 20/20

(57) ABSTRACT

Certain aspects of the present disclosure provide techniques and apparatus for testing integrated circuits. An example method generally includes generating an actual test data set from testing an integrated circuit (IC). Using at least one machine learning model and based on the actual test data set, a predicted test data set is generated. Generally, the at least one machine learning model comprises a predictive model associated with a first test defined for the IC. Based at least on the predicted test data set and a target result associated with the first test, a test result status is determined for the IC.

### INTRODUCTION

Aspects of the present disclosure relate to integrated circuit testing.

Integrated circuits (ICs) are electronic circuits including transistors and other components formed on a substrate and connected via interconnects to implement various functionality. For example, ICs may be designed and fabricated to form a complete processing unit, such as a central processing unit (CPU), graphics processing unit (GPU), neural processing unit (NPU), digital signal processor (DSP), application-specific integrated circuit (ASIC), system-on-a-chip (SoC), or the like.

During fabrication, samples of integrated circuits are tested to ensure that these integrated circuit samples operate according to a defined specification for a design of the integrated circuit. These tests may be designed to cover various logic paths within an integrated circuit to verify that the integrated circuit sample, as fabricated, generates a correct result along some given logic path and does so according to various timing constraints defined for the integrated circuit. These tests may also cover the performance of an integrated circuit for different variations in fabrication and/or operating parameters (also known as process-voltage-temperature (PVT) test cases). Because there are a large number of tests that can be run to verify the performance of an integrated circuit, testing integrated circuits may be a resource-intensive process.

### BRIEF SUMMARY

Certain aspects provide a method for testing integrated circuits. An example method generally includes generating an actual test data set from testing an integrated circuit (IC). Using at least one machine learning model and based on the actual test data set, a predicted test data set is generated. Generally, the at least one machine learning model comprises a predictive model associated with a first test defined for the IC. Based at least on the predicted test data set and a target result associated with the first test, a test result status is determined for the IC.

Other aspects provide processing systems configured to perform the aforementioned methods as well as those described herein; non-transitory, computer-readable media comprising instructions that, when executed by one or more processors of a processing system, cause the processing system to perform the aforementioned methods as well as those described herein; a computer program product embodied on a computer-readable storage medium comprising code for performing the aforementioned methods as well as those further described herein; and a processing system comprising means for performing the aforementioned methods as well as those further described herein.

The following description and the related drawings set forth in detail certain illustrative features of one or more aspects.

### BRIEF DESCRIPTION OF THE DRAWINGS

The appended figures depict certain features of one or more aspects of the present disclosure and are therefore not to be considered limiting of the scope of this disclosure.

FIG. 1 illustrates an example pipeline for testing integrated circuits.

FIG. 2 illustrates an example pipeline for testing integrated circuits using machine learning models, according to certain aspects of the present disclosure.

FIG. 3 illustrates example operations that may be performed by an integrated circuit testing system to test an integrated circuit based on a machine learning model, according to certain aspects of the present disclosure.

FIG. 4 illustrates an example system on which certain aspects of the present disclosure may be performed.

To facilitate understanding, identical reference numerals have been used, where possible, to designate identical elements that are common to the drawings. It is contemplated that elements and features of one aspect may be beneficially incorporated in other aspects without further recitation.

### DETAILED DESCRIPTION

Aspects of the present disclosure provide apparatuses, methods, processing systems, and computer-readable mediums for testing integrated circuits based on machine learning models.

Integrated circuits may be defined in terms of individual circuits, sub-systems, and/or a system-on-a-chip (SoC). Various test cases may be executed on individual circuits, sub-systems, and the SoC itself to ensure that the SoC and its subsystems operate as expected. For example, the SoC and its subsystems may be tested to ensure that timing constraints are met so that a signal does not arrive too early or too late relative to an expected time of arrival. Additionally, after smaller components are verified, larger components incorporating these smaller components may be tested against the various test cases to ensure that these larger components also meet the timing constraints. Further, during production of an integrated circuit, test cases performed on samples of the integrated circuit may similarly be performed to determine whether these samples meet a minimum specification, to “bin” samples of integrated circuits into different performance or specification categories, or the like.

Testing integrated circuits is generally a time-intensive process. As the number of test cases increases for a given integrated circuit, the computing resources (processing time, memory, etc.) may similarly increase. Thus, for an integrated circuit with a large number of test cases to be tested (e.g., corresponding to different portions of a circuit, functions to be executed on the integrated circuit, process parameters, operating voltages (corresponding to processor speed), operating temperatures, and the like), computational resources utilization for testing an integrated circuit on an individual component, sub-system, and SoC level may correspondingly increase.

In integrated circuit fabrication, testing integrated circuits may be a time-consuming process due to the number of tests defined for integrated circuits that in turn increase in size in complexity as features are introduced into new integrated circuit designs. Because the universe of tests defined for and executed on an integrated circuit is voluminous, testing samples of integrated circuits may be a time-intensive process, which may be exacerbated as the number of samples of integrated circuits to be tested increases (e.g., as an integrated circuit design moves from a prototyping stage to a high volume manufacturing stage). To reduce the number of tests to execute on a sample of an integrated circuit during testing, and thus to reduce the amount of time used in testing integrated circuits, various techniques such as reject oriented analysis (RoA) can be used. However, RoA or other test reduction techniques may provide for the elimination of some tests (e.g., tests associated with low failure rates), but may still result in the execution of tests with higher failure rates.

Aspects of the present disclosure provide techniques and apparatus for testing integrated circuits using machine learning models. As discussed in further detail herein, tests executed on an integrated circuit may be simulated using machine learning models trained to predict a result of a test based on test data sets generated for the integrated circuit. In some aspects, a first test may be executed on an integrated circuit in parallel with a second test being simulated using a machine learning model. By simulating tests using a machine learning model, aspects of the present disclosure may reduce the number of tests executed on a sample of an integrated circuit, which may reduce the amount of time and other resources used in testing samples of integrated circuits.

### Example Integrated Circuit Testing Pipeline

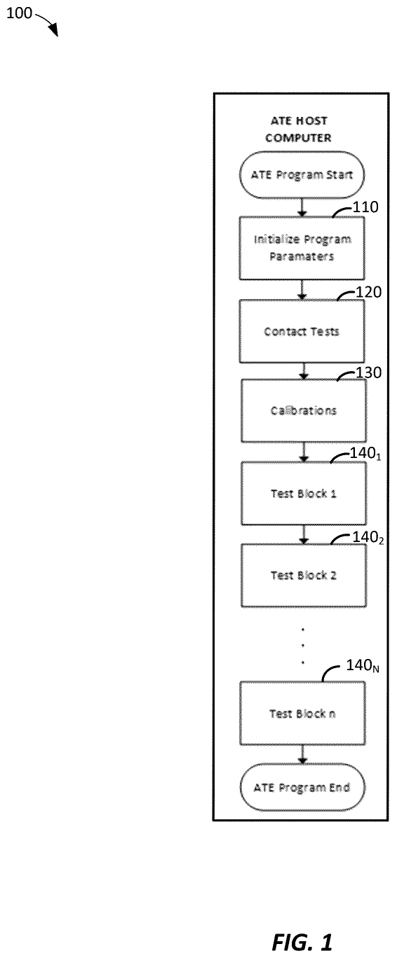

FIG. 1 illustrates an example testing pipeline 100 in which integrated circuits are tested against a plurality of test cases. The testing pipeline 100 may be executed on a computing device, such as an automated test equipment (ATE) host computer or other computing device, that can execute tests on a sample of an integrated circuit.

To test a sample of an integrated circuit, the testing pipeline 100 may begin at block 110 with initializing test program parameters to perform various tests on the integrated circuit sample. These test program parameters may include, for example, parameters defining a type of the test program, a target insertion (e.g., for probes or other metrology devices used to test a sample of an integrated circuit), test program content, customer-specific or user-specific data, or the like. The integrated circuit sample may be communicatively coupled with the ATE host computer on which the tests are to be performed and on which block 110 executes to initialize these test program parameters. In some aspects, block 110 may also or alternatively include retrieving test program parameter information from a remote data source, such as cloud storage, in which test data is stored.

Subsequently, the testing pipeline performs contact tests 120 on the sample of the integrated circuit. Generally, these contact tests 120 may be performed (e.g., using a bed-of-nails tester or other test device that can apply voltages and/or currents to different pins, contact pads, etc. of an integrated circuit) to test electrical contacts on the integrated circuit sample connected to the ATE host computer and determine whether the integrated circuit sample can be tested. For example, these contact tests may be performed to check that power contacts on the integrated circuit sample are connected and allow the integrated circuit sample to draw power across different circuit blocks of the integrated circuit, to check that ground contacts are connected, and the like. If the integrated circuit sample fails the contact tests 120, testing may be terminated, and the sample may be rejected.

Calibrations 130 may be performed on the integrated circuit sample after the sample has passed the contact tests 120. Generally, the calibrations 130 may be performed to identify parameters of tunable or adjustable circuits to meet baseline parameters defined for the integrated circuit. For example, the calibrations 130 may include calibrations to the integrated circuit for impedance matching and/or oscillator trimming, to allow the circuit to meet defined radio frequency (RF) amplitude parameters (e.g., ability to recover an RF signal at a defined minimum receive power, etc.), and the like.

After the calibrations 130 are performed, a plurality of test blocks 1401 through 140_{N} (collectively referred to as “test blocks 140”) may be executed on the integrated circuit sample connected to the ATE host computer based on the previously performed calibrations 130 and inputs into the integrated circuit sample defined for at least some of the test blocks 140. These test blocks 140 may be used, for example, to determine whether the integrated circuit sample operates properly (e.g., generates an expected result for a given input), operates within a defined specification (e.g., with respect to power draw, clock frequency, etc.), to “bin” the integrated circuit sample into one of a plurality of performance or quality bins, or the like.

Generally, in the pipeline 100, test blocks 140 may be performed sequentially. That is, the execution of a test associated with a first test block (e.g., the test block 140₁) may be completed prior to beginning execution of a test associated with a second test block (e.g., the test block 140₂). Because test blocks 140 generally execute sequentially, execution of the tests defined for an integrated circuit may be a time-consuming process.

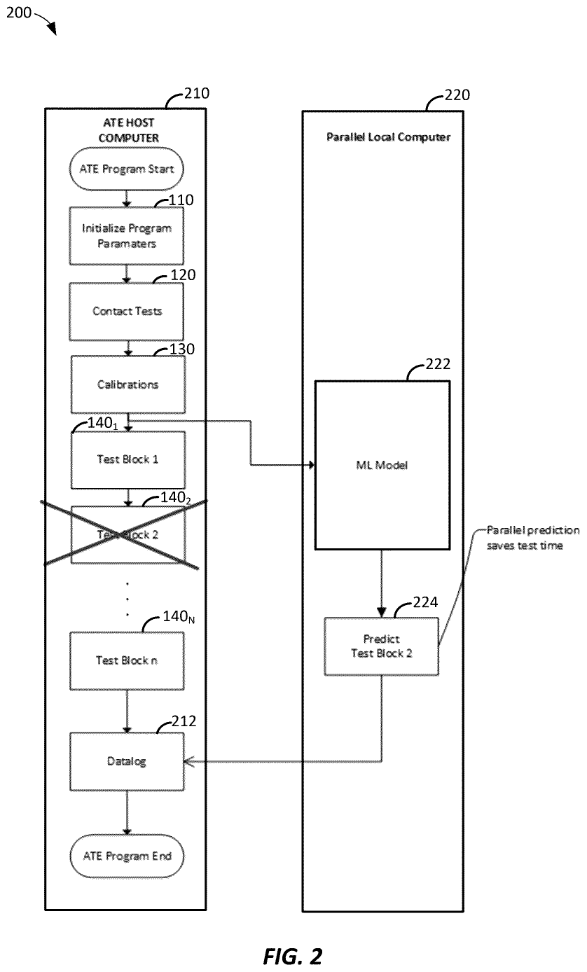

FIG. 2 illustrates an example pipeline 200 for testing integrated circuits using machine learning models, according to certain aspects of the present disclosure. As illustrated, the pipeline 200 includes testing performed on an ATE host computer 210 and testing simulated using a machine learning model 222 deployed to a local test computer 220, as discussed in further detail herein. In some aspects, the ATE host computer 210 and the local test computer 220 may be separate computing devices. In some aspects, the ATE host computer 210 and the local test computer 220 may be co-located. For example, the ATE host computer 210 may be associated with a first set of processing cores of a computing system, and the local test computer 220 may be associated with a second set of processing cores of the computing system.

As illustrated, to perform tests on a sample of an integrated circuit, test program parameter initialization (at block 110), contact tests 120, and calibrations 130 may be performed as discussed above with respect to FIG. 1. The calibration data, as illustrated, may be input into the test blocks 140 and the machine learning model 222 for use in performing tests on a sample of an integrated circuit communicatively coupled with the ATE host computer 210 and predicting results of test blocks using the machine learning model 222.

The machine learning model 222 may be a model trained to simulate or otherwise predict the results of a test block (e.g., the test block 1402, which is not executed on the ATE host computer 210) based on a set of inputs associated with calibration parameters for the integrated circuit sample under test generated at calibrations 130. In some aspects, the machine learning model 222 may be a gradient boosting machine learning model that generates a predicted output associated with the results of a test block from calibration parameters generated at calibrations 130. For example, to test a radio frequency (RF) path of an integrated circuit, the calibration parameters generated at calibrations 130 may include various direct current (DC) calibration parameters, such as DC calibration parameters associated with a voltage-controlled oscillator (VCO), DC calibration parameters associated with a low-dropout regulator (LDO), or the like. The gradient boosting machine learning model may be trained to predict the analog performance of the RF path of the integrated circuit; for example, the machine learning model may be trained to generate predictions of the in-phase and quadrature components of an RF signal generated through the RF path of the integrated circuit.

While the machine learning model 222 illustrated in FIG. 2 is illustrated as generating a prediction for a specific test block which is omitted from execution on the ATE host computer 210, it should be recognized that the machine learning model 222 may be trained to generate predictions for any number of test blocks 140 associated with tests defined for the integrated circuit sample.

During testing of the integrated circuit sample, test blocks 140 (excluding the test block 140₂, which is omitted in lieu of a prediction 224 generated by the machine learning model 222) and the machine learning model 222 may execute in parallel (e.g., on the same or different computing systems). In some aspects, though not illustrated in FIG. 2, any number of machine learning models (including the machine learning model 222) may be deployed to generate predictions for tests defined for the integrated circuit. For example, a plurality of machine learning models, each of which may be trained for a different test or set of tests, may operate in parallel (or substantially in parallel) to generate predictions for a set of tests.

The results of executing the test blocks 140 and the predictions generated by the machine learning model 222 (e.g., the prediction 224 associated with the test block 1402, amongst others not illustrated in FIG. 1) may be committed to a datalog 212. The data in the datalog 212 may be used, for example, to generate a test result status for the integrated circuit sample under test. In one example, a test result status may be associated with acceptance or rejection of the integrated circuit sample. Generally, an accepted sample may correspond to a sample for which the results of executing the test blocks 140 and the prediction 224 for an omitted test block conform to a minimum defined set of performance parameters for the integrated circuit. Meanwhile, a rejected sample may correspond to a sample for which the results of executing the test blocks 140 and the prediction 224 for an omitted test block do not conform to the minimum defined set of performance parameters for the integrated circuit, or diverge from the minimum defined set of performance parameters by a threshold amount. In some aspects, the test results and predictions in the datalog 212 may be used to flag a sample of an integrated circuit for further testing (e.g., if the results of a test block 140 or predicted results of a test block 140 are inconsistent, etc.).

In some aspects, the test results and predictions in the datalog 212 may be used to classify samples of an integrated circuit into one of a variety of bins. For example, the test results and predictions in the datalog 212 may be used to classify a sample of an integrated circuit into one of a plurality of performance-related bins (e.g., “good” performance, “better” performance, “best” performance, etc.) or one of a plurality of grade-related bins (e.g., “industrial” grade parts having more stringent performance characteristics than “commercial” grade parts, etc.).

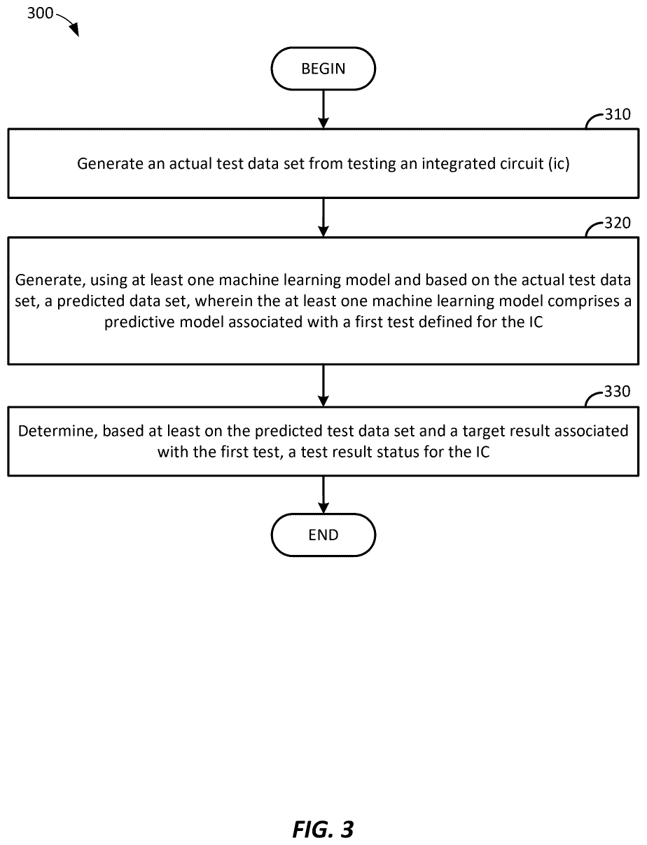

FIG. 3 illustrates example operations 300 that may be performed by an integrated circuit testing system (e.g., a system implementing the pipeline 200 illustrated in FIG. 2) to test samples of an integrated circuit, according to certain aspects of the present disclosure.

As illustrated, the operations 300 begin at block 310, with generating an actual test data set from testing an integrated circuit. The actual test data set may, for example, include a plurality of configuration parameters associated with the integrated circuit. In some aspects, generating the actual test data set may include executing a built-in self-test (BIST) procedure on the IC that generates the calibration parameters and other parameters usable as inputs for performing one or more tests on the integrated circuit and/or predicting the results of one or more tests on the IC without executing the tests on the integrated circuit.

At block 320, the operations 300 proceed with generating, using at least one machine learning model and based on the actual test data set, a predicted test data set,. Generally, the at least one machine learning model comprises a predictive model associated with a first test defined for the integrated circuit.

In some aspects, generating the predicted test data set is performed substantially in parallel with executing a second test on the integrated circuit.

At block 330, the operations 300 proceed with determining, based at least on the predicted test data set and a target result associated with the first test, a test result status for the integrated circuit.

In some aspects, the actual test data set comprises direct current measurements for a path in the integrated circuit and wherein the predicted test data set comprises predicted radio frequency (RF) performance of the path in the integrated circuit. In some aspects, the actual test data may also or alternatively include radio frequency circuitry measurements for a path in the integrated circuit, analog measurements, or other actual test data that can be used as inputs into a test. The predicted test data set may also or alternatively include speed performance measurements (e.g., a number of operations performed per second), internal latency measurements (e.g., cache latency, etc.), or other measurements that illustrate the performance of a sample of an integrated circuit.

In some aspects, the predictive model is a gradient boosting network. In some aspects, the predictive model may be a convolutional neural network, a recurrent neural network, or other machine learning model that can be used to generate a prediction of performance metrics for a test given an input of calibration parameters and/or other input data used to perform a test on an integrated circuit.

In some aspects, a total number of tests performed on the IC is less than a total number of tests defined for the IC and wherein the one or more machine learning models are used to predict results of a number of tests equal to a difference between the total number of tests defined for the IC and the total number of tests performed on the IC.

In some aspects, the test result status comprises one of accept, reject, flag, or a classification.

In some aspects, generating the actual test data set comprises using a test computer, and generating the predicted test data set comprises using at least one core in parallel with the test computer. In some aspects, the at least one core comprises a processing core of the IC. In some aspects, the at least one core comprises a processing device communicatively coupled with the test computer.

### Example Processing System for Machine-Learning-Based Integrated Circuit Testing

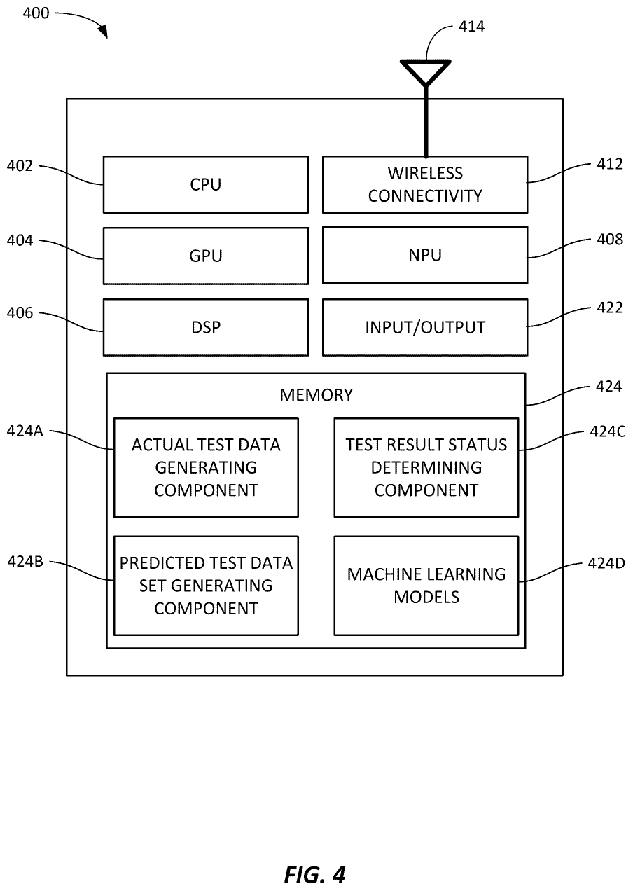

FIG. 4 depicts an example processing system 400 for selecting test cases for machine-learning-based integrated circuit testing, such as described herein for example with respect to FIGS. 2-3.

The processing system 400 includes a central processing unit (CPU) 402, which in some examples may be a multi-core CPU. Instructions executed at the CPU 402 may be loaded, for example, from a program memory associated with the CPU 402 or may be loaded from a memory 424.

The processing system 400 also includes additional processing components tailored to specific functions, such as a graphics processing unit (GPU) 404, a digital signal processor (DSP) 406, a neural processing unit (NPU) 408, and a wireless connectivity component 412.

An NPU, such as the NPU 408, is generally a specialized circuit configured for implementing control and arithmetic logic for executing machine learning algorithms, such as algorithms for processing artificial neural networks (ANNs), deep neural networks (DNNs), random forests (RFs), and the like. An NPU may sometimes alternatively be referred to as a neural signal processor (NSP), tensor processing unit (TPU), neural network processor (NNP), intelligence processing unit (IPU), vision processing unit (VPU), or graph processing unit.

NPUs, such as the NPU 408, are configured to accelerate the performance of common machine learning tasks, such as image classification, machine translation, object detection, and various other predictive models. In some examples, a plurality of NPUs may be instantiated on a single chip, such as a system on a chip (SoC), while in other examples such NPUs may be part of a dedicated neural-network accelerator.

NPUs may be optimized for training or inference, or in some cases configured to balance performance between both. For NPUs that are capable of performing both training and inference, the two tasks may still generally be performed independently.

NPUs designed to accelerate training are generally configured to accelerate the optimization of new models, which is a highly compute-intensive operation that involves inputting an existing dataset (often labeled or tagged), iterating over the dataset, and then adjusting model parameters, such as weights and biases, in order to improve model performance. Generally, optimizing based on a wrong prediction involves propagating back through the layers of the model and determining gradients to reduce the prediction error.

NPUs designed to accelerate inference are generally configured to operate on complete models. Such NPUs may thus be configured to input a new piece of data and rapidly process this new piece through an already trained model to generate a model output (e.g., an inference).

In some implementations, the NPU 408 is a part of one or more of the CPU 402, the GPU 404, and/or the DSP 406.

In some examples, the connectivity component 412 may include subcomponents, for example, for third generation (3G) connectivity, fourth generation (4G) connectivity (e.g., Long-Term Evolution (LTE)), fifth generation (5G) connectivity (e.g., New Radio (NR)), Wi-Fi connectivity, Bluetooth connectivity, and other wireless data transmission standards. The connectivity component 412 may be further coupled to one or more antennas 414.

The processing system 400 may also include one or more input and/or output devices 422, such as screens, touch-sensitive surfaces (including touch-sensitive displays), physical buttons, speakers, microphones, and the like.

In some examples, one or more of the processors of the processing system 400 may be based on an ARM or RISC-V instruction set.

The processing system 400 also includes a memory 424, which is representative of one or more static and/or dynamic memories, such as a dynamic random access memory, a flash-based static memory, and the like. In this example, the memory 424 includes computer-executable components, which may be executed by one or more of the aforementioned processors of the processing system 400.

In particular, in this example, the memory 424 includes an actual test data generating component 424A, a predicted test data set generating component 424B, a test result status determining component 424C, and machine learning models 424D. The depicted components, and others not depicted, may be configured to perform various aspects of the methods described herein.

### Example Clauses

Implementation details of various aspects of the present disclosure are described in the following numbered clauses:

Clause 1: A processor-implemented method for integrated circuit testing, comprising: generating an actual test data set from testing an integrated circuit (IC);

generating, using at least one machine learning model and based on the actual test data set, a predicted test data set, wherein the at least one machine learning model comprises a predictive model associated with a first test defined for the IC; and determining, based at least on the predicted test data set and a target result associated with the first test, a test result status for the IC.

Clause 2: The method of Clause 1, wherein generating the actual test data set comprises executing a built-in self-test procedure on the IC.

Clause 3: The method of Clause 2, wherein the actual test data set comprises calibration parameters generated by executing the built-in self-test procedure on the IC.

Clause 4: The method of any of Clauses 1 through 3, wherein generating the predicted test data set is performed substantially in parallel with executing a second test on the IC.

Clause 5: The method of any of Clauses 1 through 4, wherein the actual test data set comprises direct current measurements for a path in the IC and wherein the predicted test data set comprises predicted radio frequency (RF) performance of the path in the IC.

Clause 6: The method of any of Clauses 1 through 5, wherein the predictive model is a gradient boosting network.

Clause 7: The method of any of Clauses 1 through 6, wherein a total number of tests performed on the IC is less than a total number of tests defined for the IC and wherein the one or more machine learning models are used to predict results of a number of tests equal to a difference between the total number of tests defined for the IC and the total number of tests performed on the IC.

Clause 8: The method of any of Clauses 1 through 7, wherein the test result status comprises one of accept, reject, flag, or a classification.

Clause 9: The method of any of Clauses 1 through 8, wherein generating the actual test data set comprises using a test computer and wherein generating the predicted test data set comprises using at least one core in parallel with the test computer.

Clause 10: The method of Clause 9, wherein the at least one core comprises a processing core of the IC.

Clause 11: The method of Clause 9 or 10, wherein the at least one core comprises a processing device communicatively coupled with the test computer.

Clause 12: An apparatus comprising: at least one memory having executable instructions stored thereon; and one or more processors configured to execute the executable instructions to cause the apparatus to perform a method in accordance with any of Clauses 1 through 11.

Clause 13: An apparatus comprising means for performing a method in accordance with any of Clauses 1 through 11.

Clause 14: A non-transitory computer-readable medium having instructions stored thereon which, when executed by a processor, perform a method in accordance with any of Clauses 1 through 11.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. A processor-implemented method for integrated circuit testing, comprising:
receiving an actual test data set from testing an integrated circuit (IC);
generating, using at least one machine learning model and based on the actual test data set, a predicted test data set, wherein the at least one machine learning model comprises a predictive model associated with a first test defined for the IC; and
outputting the predicted test data set for determination of a test result status for the IC, based at least on the predicted test data set and a target result associated with the first test.

2. The method of claim 1, wherein the actual test data set is from a built-in self-test procedure executed on the IC.

3. The method of claim 2, wherein the actual test data set comprises calibration parameters generated by executing the built-in self-test procedure on the IC.

4. The method of claim 1, wherein generating the predicted test data set is performed substantially in parallel with executing a second test on the IC.

5. The method of claim 1, wherein the actual test data set comprises direct current measurements for a path in the IC and wherein the predicted test data set comprises predicted radio frequency (RF) performance of the path in the IC.

6. The method of claim 1, wherein the predictive model is a gradient boosting network.

7. The method of claim 1, wherein a total number of tests performed on the IC is less than a total number of tests defined for the IC and wherein the at least one machine learning model is used to predict results of a number of tests equal to a difference between the total number of tests defined for the IC and the total number of tests performed on the IC.

8. The method of claim 1, wherein the test result status comprises one of accept, reject, flag, or a classification.

9. The method of claim 1, wherein the actual test data set is received from a test computer and wherein generating the predicted test data set comprises using at least one core operating in parallel with the test computer.

10. The method of claim 9, wherein the at least one core comprises a processing core of the IC.

11. The method of claim 9, wherein the at least one core comprises a processing device communicatively coupled with the test computer.

12. A processing system for integrated circuit testing, comprising:
at least one memory having executable instructions stored thereon; and
one or more processors configured to execute the executable instructions in order to cause the processing system to:
receive an actual test data set from testing an integrated circuit (IC);
generate, using at least one machine learning model and based on the actual test data set, a predicted test data set, wherein the at least one machine learning model comprises a predictive model associated with a first test defined for the IC; and
output the predicted test data set for determination of a test result status for the IC based at least on the predicted test data set and a target result associated with the first test.

13. The processing system of claim 12, wherein the actual test data set is from a built-in self-test procedure executed on the IC.

14. The processing system of claim 12, wherein to generate the predicted test data set, the one or more processors are configured to execute the executable instructions in order to cause the processing system to generate the predicted test data set substantially in parallel with execution of a second test on the IC.

15. The processing system of claim 12, wherein the actual test data set comprises direct current measurements for a path in the IC and wherein the predicted test data set comprises predicted radio frequency (RF) performance of the path in the IC.

16. The processing system of claim 12, wherein the predictive model is a gradient boosting network.

17. The processing system of claim 12, wherein a total number of tests configured to be performed on the IC is less than a total number of tests defined for the IC and wherein the at least one machine learning model is used to predict results of a number of tests equal to a difference between the total number of tests defined for the IC and the total number of tests configured to be performed on the IC.

18. The processing system of claim 12, wherein the test result status comprises one of accept, reject, flag, or a classification.

19. The processing system of claim 12, wherein the actual test data set is configured to be received from a test computer and wherein to generate the predicted test data set, the one or more processors are configured to execute the executable instructions in order to cause the processing system to generate the predicted test data set using at least one core operated in parallel with the test computer.

20. A non-transitory computer-readable medium having executable instructions stored thereon which, when executed by one or more processors, perform an operation for integrated circuit testing, the operation comprising:
receiving an actual test data set from testing an integrated circuit (IC);
generating, using at least one machine learning model and based on the actual test data set, a predicted test data set, wherein the at least one machine learning model comprises a predictive model associated with a test defined for the IC; and
outputting the predicted test data set for determination of a test result status for the IC, based at least on the predicted test data set and a target result associated with the test.
